(19) United States
(12) Patent Application Publication
(10) Pub. No.: US 2009/0200644 A1
(43) Pub. Date: Aug. 13, 2009

(54) SEMICONDUCTOR DEVICE AND METHOD FOR MANUFACTURING SEMICONDUCTOR DEVICE

(75) Inventor: Takayuki Hisaka, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/164,168

(22) Filed: Jun. 30, 2008

(30) Foreign Application Priority Data
Feb. 12, 2008 (JP) 2008-030852

(51) Int. Cl. H01L 21/283; H01L 29/12

(52) U.S. Cl. 257/613; 438/605; 257/E29.068; 257/E21.159

(57) ABSTRACT

A semiconductor device includes a semiconductor layer, an electrode connected to the semiconductor layer, a sacrificial metal layer connected to the electrode and made of a metal having higher ionization tendency than the material of the semiconductor layer and the material of the electrode.

### BACKGROUND OF THE INVENTION

1. Field of the Invention

The present invention relates to a semiconductor device and more particularly to a semiconductor device having a configuration that allows the device to be manufactured in such a way as to prevent corrosion of its semiconductor layer in the cleaning process of the device. The invention also relates to a method for manufacturing a semiconductor device and more particularly to a method for manufacturing a semiconductor device in such a way as to prevent corrosion of its semiconductor layer in the cleaning process of the device.

2. Background Art

The manufacture of a semiconductor device includes a cleaning process for removing residual impurities on the surface of the device. There is a known method of preventing corrosion of the wiring layers of a semiconductor device in such a cleaning process, as disclosed in the following Patent Document 1.

The present inventors are aware of the following document as a related art of the present invention. [Patent Document 1] Japanese Laid-Open Patent Application Publication No. Hei 07-66198

The residual impurities on the surface of a semiconductor device may reduce the reliability of the semiconductor device, requiring that the device be sufficiently cleaned by a cleaning process. On the other hand, the cleaning of the semiconductor device may result in corrosion of its surface. The above conventional method is used to prevent corrosion of the wiring layers in the surface of a semiconductor device in the cleaning process, but it cannot be used to prevent corrosion of other portions of the semiconductor device.

It may happen that the cleaning process causes corrosion of portions of the semiconductor device other than the wiring layers in its surface. The present inventors have found that full cleaning of a semiconductor device results in significant corrosion of the semiconductor layer formed in its surface. The corrosion of the semiconductor layer may lead to a reduction in the output current of the semiconductor device. It should be noted that it is desired to reduce the thickness of the semiconductor layer in order to enhance the performance of the semiconductor device. However, the thinner the semiconductor layer, the greater the impact of its corrosion, as is known in the art.

### SUMMARY OF THE INVENTION

The present invention has been devised to solve the above problems. It is, therefore, an object of the present invention to provide a semiconductor device having a configuration that allows the device to be manufactured in such a way as to prevent corrosion of its semiconductor layer in the cleaning process of the device. Another object of the invention is to provide a method for manufacturing a semiconductor device in such a way as to prevent corrosion of its semiconductor layer in the cleaning process of the device.

The above objects of the present invention are achieved by a semiconductor device described below. The semiconductor device includes a semiconductor layer, an electrode connected to said semiconductor layer, a sacrificial metal layer connected to said electrode and made of a metal having higher ionization tendency than the material of said semiconductor layer and the material of said electrode.

The above objects of the present invention are also achieved by a semiconductor device described below. The semiconductor device includes a semiconductor layer, an electrode connected to said semiconductor layer, a sacrificial semiconductor layer electrically connected to said electrode through said semiconductor layer and made of a semiconductor having higher ionization tendency than the material of said semiconductor layer and the material of said electrode.

The above objects of the present invention are also achieved by a method for manufacturing a semiconductor device described below. The semiconductor device includes a semiconductor layer and an electrode connected to the semiconductor layer. The method includes steps described below. One of the steps is providing a semiconductor wafer. Another of the steps forming the semiconductor device and an electrical contact region in the semiconductor wafer such that the electrical contact region is electrically connected to the semiconductor layer of the semiconductor device. Another of the steps is connecting a conductor to the electrical contact region. The conductor is allow a negative potential to be applied to the electrical contact region relative to the potential of a cleaning liquid. Another of the steps is immersing the semiconductor wafer in the cleaning liquid. Another of the steps is cleaning the semiconductor wafer while applying the negative potential to said electrical contact region.

The above objects of the present invention are also achieved by a method for manufacturing a semiconductor device described below. The semiconductor device includes a semiconductor layer and an electrode connected to the semiconductor layer. The method includes steps described below. One of the steps is providing a semiconductor wafer. Another of the steps is forming the semiconductor device, an electrical contact region being electrically connected to the semiconductor layer, and an electrode connecting portion being electrically connected to the electrode. Another of the steps is connecting conductors to the electrical contact region and the electrode connecting portion. The conductors allow a potential difference to be applied between the electrical contact region and the electrode connecting portion. Another of the steps is immersing the semiconductor wafer in a cleaning liquid and cleaning the semiconductor wafer while applying a negative potential to said electrical contact region relative to said electrode connecting portion.

Other objects and further features of the present invention will be apparent from the following detailed description when read in conjunction with the accompanying drawings.

### BRIEF DESCRIPTION OF THE DRAWINGS

FIG. 1 is a vertical cross-sectional view of a semiconductor device according to a first embodiment;

FIGS. 2A and 2B are a vertical cross-sectional view of a semiconductor device in which the sacrificial metal layer shown in FIG. 1 is omitted;

FIG. 3 is a vertical cross-sectional view of a semiconductor device according to a second embodiment;

FIG. 4 is a vertical cross-sectional view of a semiconductor device according to a variation of a second embodiment;

FIGS. 5A-5C show a semiconductor wafer according to a third embodiment;

FIG. 6 is a diagram illustrating a cleaning process for a semiconductor device or wafer according to a third embodiment;

FIG. 7 is a plan view showing a semiconductor wafer according to a fourth embodiment;

FIG. 8 is a diagram illustrating a cleaning process for a semiconductor device or wafer according to a fourth embodiment; and

FIG. 9 is a diagram illustrating a cleaning process for a semiconductor device or wafer according to a variation of a fourth embodiment;

### DETAILED DESCRIPTION OF THE PREFERRED EMBODIMENTS

Now, embodiments of the present invention will be described with reference to the drawings. Like reference numerals denote like components throughout the drawings, and redundant descriptions will be omitted.

### First Embodiment

### [Device Configuration]

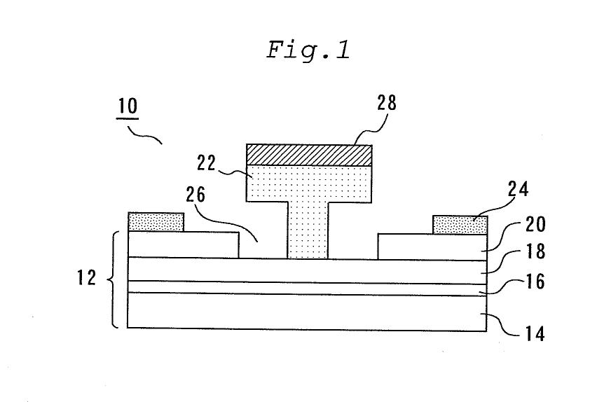

A first embodiment of the present invention relates to a semiconductor device having a configuration that allows the device to be manufactured in such a way as to prevent corrosion of its semiconductor layer in the cleaning process of the device. FIG. 1 is a vertical cross-sectional view of a semiconductor device 10 according to the present embodiment. This semiconductor device 10 is a high electron mobility transistor and includes a semiconductor layer 12. The semiconductor layer 12 includes a buffer layer 14, a channel layer 16, an electron supply layer 18, and a contact layer 20 sequentially formed on top of one another, as shown in FIG. 1. The electron supply layer 18 is made of AlGaAs, and the contact layer 20 is GaAs doped with a high concentration of a donor. The semiconductor device 10 further includes a gate electrode 22 disposed at its center and includes ohmic electrodes 24 disposed at both ends of the device. The gate electrode 22 is connected to the electron supply layer 18, and the ohmic electrodes 24 are connected to the contact layer 20. The gate electrode 22 is separated from the contact layer 20 by a recess 26. The gate electrode 22 is made of Al. On the gate electrode 22, a sacrificial metal layer 28 of Mo is formed. Mo, of which the sacrificial layer 28 is made, has higher ionization tendency than Al, of which the gate electrode 22 is made.

### [Function of Device Configuration]

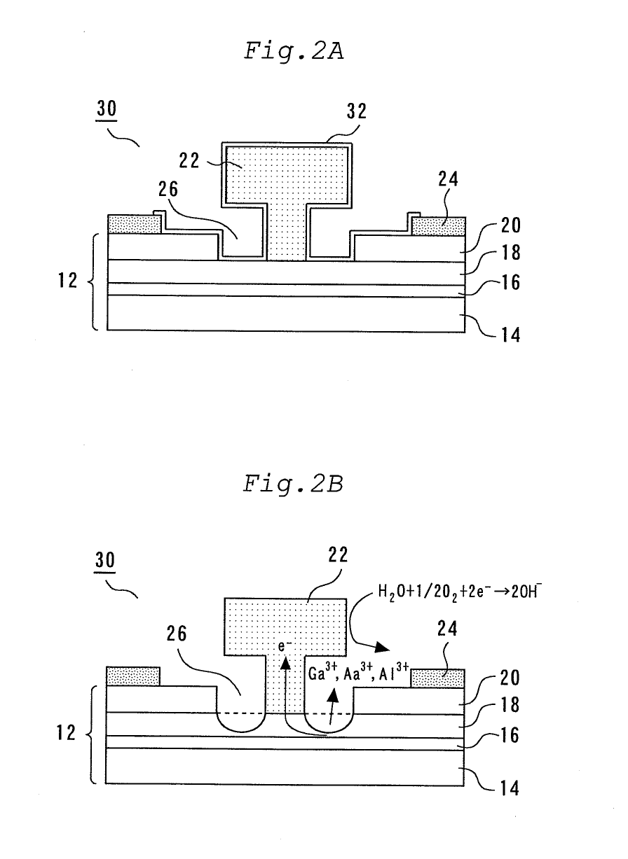

FIGS. 2A and 2B show a semiconductor device 30, which is a variation of the semiconductor device 10, in which the sacrificial metal layer 28 is omitted. FIG. 2A is a cross-sectional view of the semiconductor device 30 after it has undergone a cleaning process. A surface protective film 32 is formed on the semiconductor device 30 after the cleaning process, as shown in FIG. 2A. FIG. 2B shows the way in which the surface of the semiconductor device 30 is etched away by the cleaning process. As described above, the gate electrode 22 is composed of Al and the electron supply layer 18 is composed of AlGaAs. Since AlGaAs has higher ionization tendency than Al, the electron supply layer 18 acts as an anode and the gate electrode 22 acts as a cathode during the cleaning process, forming an electrochemical cell, as shown in FIG. 2B. As a result, the surface of the electron supply layer 18 is oxidized and etched. This may reduce the reliability and performance of the semiconductor device 30.

In the case of the semiconductor device 10 of the present embodiment, on the other hand, the material (Mo) of the sacrificial metal layer 28 has higher ionization tendency than the material (Al) of the gate electrode 22, as described above. Therefore, the sacrificial metal layer 28 acts as an anode and the gate electrode 22 acts as a cathode during the cleaning process, forming a different electrochemical cell. As a result, the sacrificial metal layer 28 is oxidized, thereby limiting the oxidation and etching of the electron supply layer 18 shown in FIG. 2B.

Thus, in the semiconductor device 10 of the present embodiment, the sacrificial metal layer 28 is formed on the gate electrode 22 to limit etching of the electron supply layer 18 in the cleaning process of the device, resulting in improved reliability and performance of the device.

### [Variation of First Embodiment]

Although the gate electrode 22 and the sacrificial metal layer 28 of the semiconductor device 10 of the present embodiment have been described as being made of Al and Mo, respectively, it is to be understood that the gate electrode 22 may be made of Au and the sacrificial metal layer 28 may be made of W.

### Second Embodiment

### [Device Configuration]

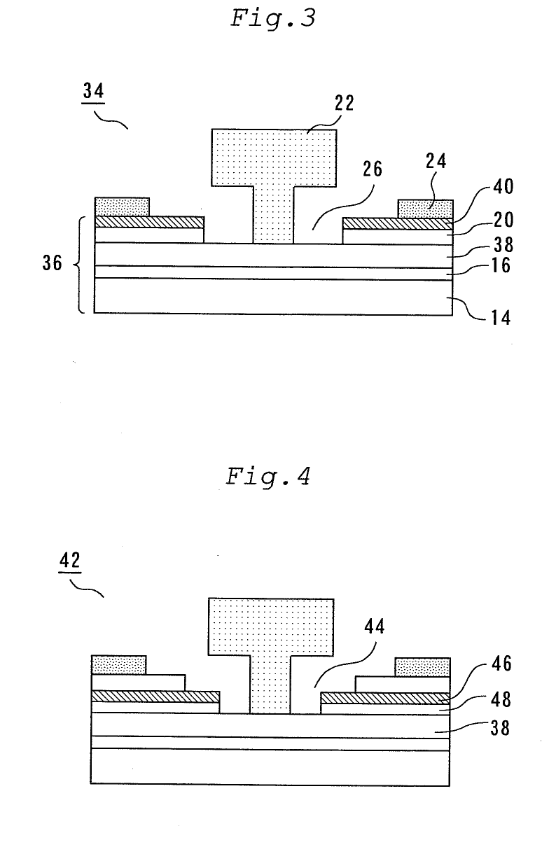

A second embodiment of the present invention relates to a semiconductor device including a sacrificial semiconductor layer which prevents corrosion of the underlying semiconductor layer in the cleaning process of the device. FIG. 3 is vertical cross-sectional view of a semiconductor device 34 according to the present embodiment. This semiconductor device 34 is a high electron mobility transistor similar to the semiconductor device 10 of the first embodiment, but, unlike the semiconductor device 10, it does not include a sacrificial metal layer 28. The semiconductor device 34 includes a semiconductor layer 36 that includes a buffer layer 14, a channel layer 16, an electron supply layer 38, and a contact layer 20 sequentially formed on top of one another, as shown in FIG. 3. Further, a sacrificial semiconductor layer 40 is formed on the surface of the contact layer 20. The electron supply layer 38 is made of Al_{0.2}Ga_{0.8}As (i.e., has an Al mole fraction of 0.2), and the sacrificial semiconductor layer 40 is made of Al_{0.4}Ga_{0.6}As (i.e., has an Al mole fraction of 0.4). In the case of AlGaAs, the higher the Al mole fraction, the higher the ionization tendency. Therefore, Al_{0.4}Ga_{0.6}As, of which the sacrificial semiconductor layer 40 is made, has higher ionization tendency than Al_{0.2}Ga_{0.8}As, of which the electron supply layer 38 is made. It should be further noted that the sacrificial semiconductor layer 40 is electrically connected to the gate electrode 22 through the contact layer 20 and the electron supply layer 38.

### [Function of Device Configuration]

In the semiconductor device 34 of the present embodiment, the material (Al_{0.4}Ga_{0.6}As) of the sacrificial semiconductor layer 40 has higher ionization tendency than the material (Al_{0.2}Ga_{0.8}As) of the electron supply layer 38, as described above. Therefore, the sacrificial semiconductor layer 40 acts as an anode and the gate electrode 22 acts as a cathode during the cleaning process, thereby forming an electrochemical cell. As a result, the sacrificial semiconductor layer 40 is oxidized as shown in FIG. 3, thereby limiting the oxidation and etching of the electron supply layer 38. That is, the electron supply layer 38 is not oxidized in the manner described in connection with the electron supply layer 18 shown in FIG. 2B.

Thus, in the semiconductor device 34 of the present embodiment, the sacrificial semiconductor layer 40 is formed on the contact layer 20 to limit etching of the electron supply layer 38 in the cleaning process of the device, resulting in improved reliability and performance of the device.

### [Variations of Second Embodiment]

Although the semiconductor device of the present embodiment has been described as having a single-stepped recess structure (as shown in FIG. 3), it is to be understood that the semiconductor device may have a different recess structure. For example, it may have a two-stepped recess structure such as the two-stepped recess structure 44 of the semiconductor device 42 shown in FIG. 4. Generally, the closer the sacrificial semiconductor layer to the recess, the greater its effect in limiting the etching of the electron supply layer 38. Therefore, the recess 44 of the semiconductor device 42 has a sacrificial semiconductor layer 46 on its first step 48, as shown in FIG. 4.

Although the sacrificial semiconductor layer 40 of the semiconductor device 34 of the present embodiment has been described as being made of Al_{0.4}Ga_{0.6}As, it is to be understood that the sacrificial semiconductor layer 40 may be made of Al_{0.8}Ga_{0.2}As (i.e., may have an Al mole fraction of 0.8).

### Third Embodiment

### [Wafer Configuration and Manufacturing Method]

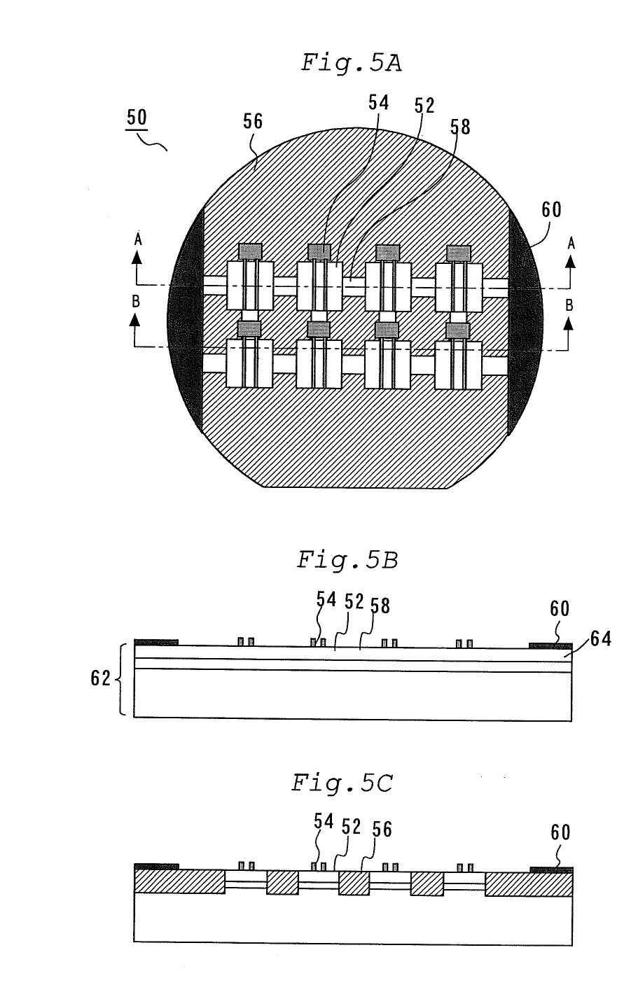

A third embodiment of the present invention relates to a method for manufacturing a semiconductor device in such a way as to prevent corrosion of its semiconductor layer in the cleaning process of the device. FIGS. 5A-5C show a semiconductor wafer 50 according to the present embodiment. Specifically, FIG. 5A is a plan view of the semiconductor wafer 50. This wafer 50 has a plurality of semiconductor devices 52 formed therein, each semiconductor device 52 having a gate electrode 54. These semiconductor devices 52 are electrically separated from each other by an insulating region 56 formed by ion implantation. However, each two adjacent semiconductor devices 52 are electrically connected to each other by a channel connecting portion 58. These channel connecting portions 58 are not ion implanted; they are formed by selectively ion implanting the wafer surface. Further, the semiconductor wafer 50 has a contact pad 60 formed on each of two diagonally opposite edges thereof, as shown in FIG. 5A. FIGS. 5B and 5C are vertical cross-sectional views of the semiconductor wafer 50 taken along lines A-A and B-B, respectively, of FIG. 5A, as viewed in the direction of the arrows. As shown in FIG. 5B, the semiconductor devices 52 and the channel connecting portions 58 are formed from the same semiconductor thin film. As viewed in the cross section of FIG. 5B, the contact pads 60 are connected to the contact layer 64 in the semiconductor layer 62 of the semiconductor wafer 50, that is, the contact pads 60 are electrically connected to the semiconductor layer 62, which extends through each semiconductor device 52. As viewed in the cross section of FIG. 5C, on the other hand, each two adjacent semiconductor devices 52 are electrically separated from each other by the insulating region 56.

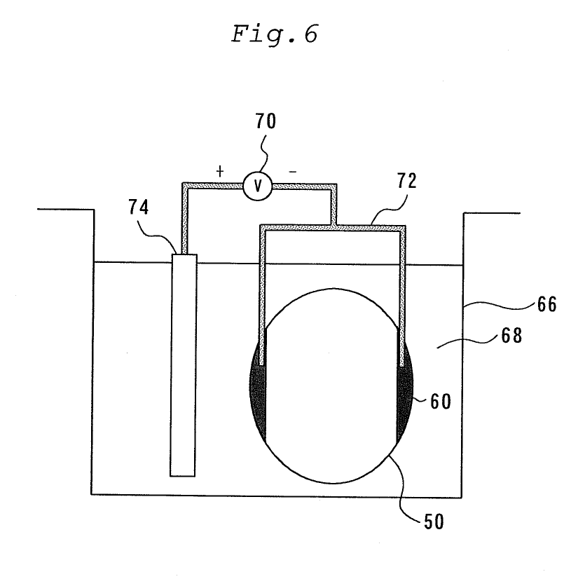

FIG. 6 is a diagram illustrating a cleaning process for a semiconductor device or wafer according to the present embodiment. In this cleaning process, the semiconductor wafer 50 is immersed in purified water 68 maintained at a low temperature in a cleaning bath 66, as shown in FIG. 6. The contact pads 60 of the semiconductor wafer 50 are connected to the negative terminal of a power supply 70 through conductors 72. An electrode bar 74 is also immersed in the purified water 68 and connected to the positive terminal of the power supply 70 through a conductor 72. The electrode bar 74 serves as the opposite electrode to the semiconductor wafer 50.

### [Operation of Cleaning Process]

In the semiconductor wafer 50, the contact pads 60 are electrically connected to the semiconductor layer 62 (which extends through each semiconductor device 52), as shown in FIGS. 5A-5C. Therefore, in this cleaning process, a negative potential relative to the electrode bar 74 is applied through the contact pads 60 to the semiconductor layer 62. As a result, the semiconductor layer 62 has a negative potential relative to the purified water 68 in contact with its surface.

Without the application of such a negative potential to the semiconductor layer 62, the gate electrodes 54 act as cathodes and the semiconductor layer 62 acts as an anode during the cleaning process, thereby forming an electrochemical cell. As a result, the surface of the semiconductor layer 62 exposed to the purified water 68 is etched. On the other hand, the application of a negative potential as described above prevents the formation of an electrochemical cell and thereby prevents etching of the semiconductor layer 62.

Thus, according to the method of the present embodiment for manufacturing a semiconductor device, the semiconductor layer 62 extending through the semiconductor devices 52 is prevented from being etched in the cleaning process, resulting in improved reliability and performance of each device.

### [Variation of Third Embodiment]

Although the present embodiment has been described in connection with a cleaning process in which purified water 68 is used as a cleaning liquid to clean the semiconductor devices, it is to be understood that a solvent such as a resist stripper, or an aqueous solution, may be used instead of purified water.

### Fourth Embodiment

### [Wafer Configuration and Manufacturing Method]

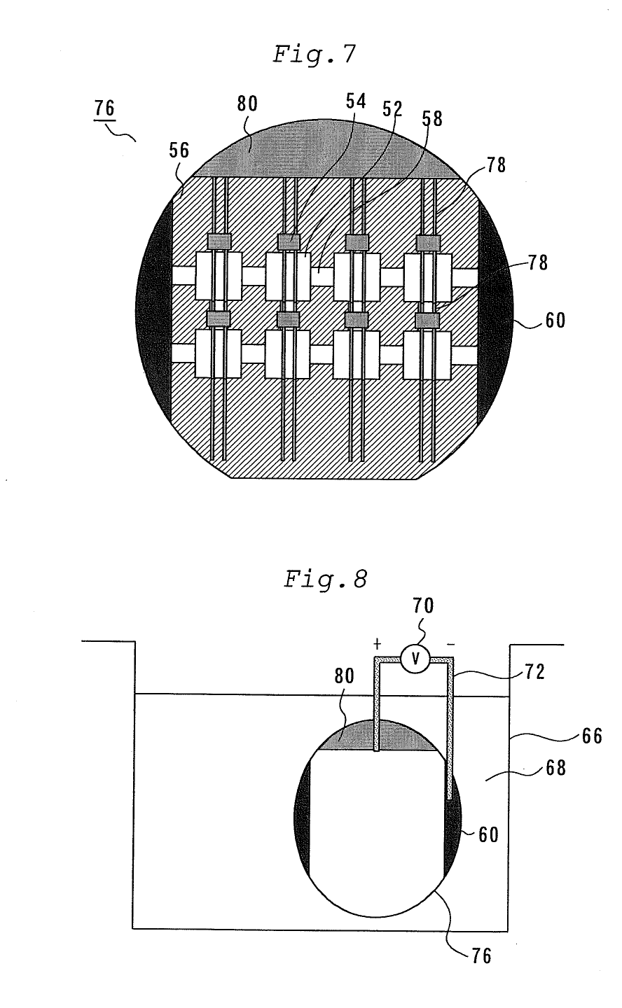

A fourth embodiment of the present invention relates to a method for manufacturing a semiconductor device in such a way as to prevent corrosion of its semiconductor layer in the cleaning process of the device. FIG. 7 is a plan view showing a semiconductor wafer 76 according to the present embodiment. The semiconductor wafer 76 includes semiconductor devices 52, channel connecting portions 58, an insulating region 56, and contact pads 60, as in the semiconductor wafer 50 of FIGS. 5A-5C. A gate electrode connecting portion 78 is formed between and electrically connects each two vertically adjacent gate electrodes 54 (as viewed in FIG. 7). Further, the semiconductor wafer 76 has a gate contact pad 80 on its upper edge (as viewed in FIG. 7). A gate electrode connecting portion 78 is also formed between the gate contact pad 80 and each adjacent gate electrode 54 to electrically connect the gate contact pad 80 and the gate electrode 54 of each semiconductor device 52.

FIG. 8 is a diagram illustrating a cleaning process for a semiconductor device or wafer according to the present embodiment. In this cleaning process, the semiconductor wafer 76 is immersed in purified water 68 in a cleaning bath 66. Further, the gate contact pad 80 and one of the contact pads 60 of the semiconductor wafer 76 are connected to the positive terminal and the negative terminal, respectively, of a power supply 70 through conductors 72.

### [Operation of Cleaning Process]

In the semiconductor wafer 76, the contact pads 60 are electrically connected to the semiconductor layer 62 (which extends through each semiconductor device 52), as in the semiconductor wafer 50 shown in FIGS. 5A-5B. Further, the gate contact pad 80 is electrically connected to the gate electrode 54 of each semiconductor device 52. Therefore, in this cleaning process, a negative potential relative to the gate electrodes 54 of the semiconductor devices 52 is applied through the contact pad 60 to the semiconductor layer 62.

Without the application of such a negative potential to the semiconductor layer 62, the gate electrodes 54 act as cathodes and the semiconductor layer 62 acts as an anode during the cleaning process, thereby forming an electrochemical cell. As a result, the surface of the semiconductor layer 62 exposed to the purified water 68 is etched. On the other hand, the application of a negative potential as described above prevents the formation of an electrochemical cell and thereby prevents etching of the semiconductor layer 62.

Thus, according to the method of the present embodiment for manufacturing a semiconductor device, the semiconductor layer 62 extending through each semiconductor device 52 is prevented from being etched in the cleaning process, resulting in improved reliability and performance of each device.

### [Variation of Fourth Embodiment]

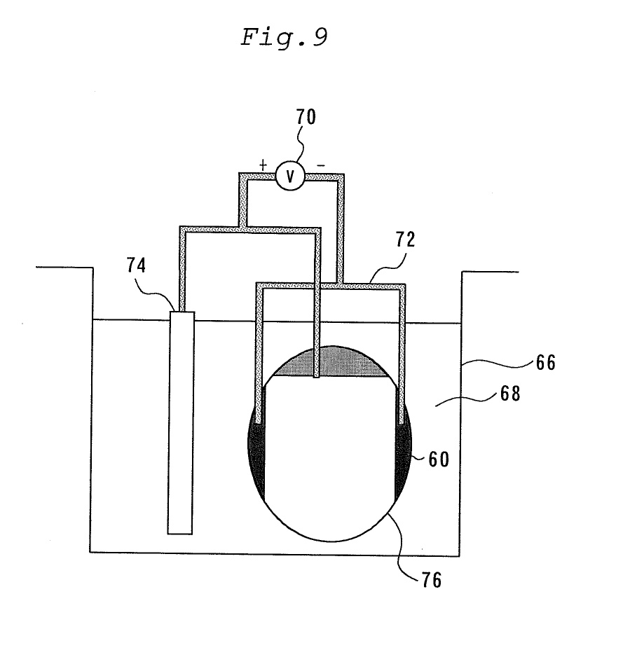

Although the method of the present embodiment has been described as including the cleaning process shown in FIG. 8, it is to be understood that the cleaning process shown in FIG. 9 may be substituted therefor. In this cleaning process, the semiconductor wafer 76 and an electrode bar 74 are immersed in the purified water 68 in the cleaning bath 66. The contact pads 60 of the semiconductor wafer 76 are connected to the negative terminal of the power supply 70 through conductors 72. Further, the gate contact pad 80 of the semiconductor wafer 76 and the electrode bar 74 are connected to the positive terminal of the power supply 70 through conductors 72. With this arrangement, a negative potential relative to both the purified wafer 68 and the gate electrodes 54 is applied through the contact pads 60 to the semiconductor layer 62 extending through each semiconductor device 52, thereby preventing etching of the semiconductor layer 62.

The major benefits of the present invention described above are summarized follows:

According to a first aspect of the present invention, a semiconductor device to be manufactured in such a way as to prevent corrosion of its semiconductor layer in the cleaning process of the device. This allows the semiconductor device to be fully cleaned in the cleaning process, resulting in improved reliability and performance of the device.

Further, the present invention is not limited to these embodiments, but variations and modifications may be made without departing from the scope of the present invention.

1. A semiconductor device comprising:
a semiconductor layer;
an electrode connected to said semiconductor layer; and
a sacrificial metal layer connected to said electrode and made of a metal having higher ionization tendency than the material of said semiconductor layer and the material of said electrode.

2. The semiconductor device according to claim 1, wherein
said electrode is Al or Au,
said semiconductor layer is AlGaAs, and
said sacrificial metal layer is Mo or W.

3. A semiconductor device comprising:
a semiconductor layer;
an electrode connected to said semiconductor layer; and
a sacrificial semiconductor layer electrically connected to said electrode through said semiconductor layer and made of a semiconductor having higher ionization tendency than the material of said semiconductor layer and the material of said electrode.

4. The semiconductor device according to claim 3, wherein
said electrode is Al or Au,
said semiconductor layer is AlGaAs, and
said sacrificial semiconductor layer is AlGaAs and has a higher Al mole fraction than said semiconductor layer.

5. A method for manufacturing a semiconductor device including a semiconductor layer and an electrode connected to said semiconductor layer, said method comprising:
providing a semiconductor wafer;
forming said semiconductor device and an electrical contact region in said semiconductor wafer such that said electrical contact region is electrically connected to said semiconductor layer of said semiconductor device;
connecting a conductor to said electrical contact region, and applying, through said conductor, a potential to said electrical contact region that is negative relative to the potential of a cleaning liquid; and
of immersing said semiconductor wafer in said cleaning liquid and cleaning said semiconductor wafer while applying the negative potential to said electrical contact region.

6. The method according to claim 5, wherein
forming said semiconductor device includes forming a connecting portion in said semiconductor wafer such that said connecting portion electrically connects said semiconductor layer to said electrical contact region, and
forming both said semiconductor layer and said connecting portion by etching a single thin film in said semiconductor wafer.

7. The method according to claim 5, wherein said electrical contact region includes a metal forming an ohmic contact with said semiconductor layer.

8. The method according to claim 6, wherein said electrical contact region includes a metal forming an ohmic contact with said semiconductor layer.

9. A method for manufacturing a semiconductor device including a semiconductor layer and an electrode connected to said semiconductor layer, said method comprising:
providing a semiconductor wafer;
forming said semiconductor device, an electrical contact region, and an electrode connecting portion, so that said electrical contact region is electrically connected to said semiconductor layer of said semiconductor device, and said electrode connecting portion is electrically connected to said electrode of said semiconductor device;
connecting conductors to said electrical contact region and said electrode connecting portion, and applying a potential difference between said electrical contact region and said electrode connecting portion; and
immersing said semiconductor wafer in a cleaning liquid and cleaning said semiconductor wafer while applying a potential to said electrical contact region that is negative relative to said electrode connecting portion.

10. The method according to claim 9, wherein
forming said semiconductor device includes forming a layer connecting portion in said semiconductor wafer such that said layer connecting portion electrically connects said semiconductor layer to said electrical contact region, and
forming both said semiconductor layer and said layer connecting portion by etching a single thin film in said semiconductor wafer.

11. The method according to claim 9, wherein said electrical contact region includes a metal forming an ohmic contact with said semiconductor layer.

12. The method according to claim 10, wherein said electrical contact region includes a metal forming an ohmic contact with said semiconductor layer.

13. The method according to claim 9, including forming both said electrode and said electrode connecting portion by etching a single thin film in said semiconductor wafer.

14. The method according to claim 10, including forming both said electrode and said electrode connecting portion by etching a single thin film in said semiconductor wafer.

15. The method according to claim 11, including forming both said electrode and said electrode connecting portion by etching a single thin film in said semiconductor wafer.

16. The method according to claim 12, including forming both said electrode and said electrode connecting portion by etching a single thin film in said semiconductor wafer.
